(19) United States
(12) Patent Application Publication
(10) Pub. No.: US 2025/0300059 A1
(43) Pub. Date: Sep. 25, 2025

(54) DOUBLE-SIDED STACKED FAN-OUT PACKAGE DEVICE AND FABRICATION METHOD THEREOF

(71) Applicant: INSTITUTE OF SEMICONDUCTORS, GUANGDONG ACADEMY OF SCIENCES, Guangzhou (CN)

(72) Inventors: Yingqiang YAN, Guangzhou (CN); Chuan HU, Guangzhou (CN); Xun XIANG, Guangzhou (CN)

(21) Appl. No.: 19/028,301

(22) Filed: Jan. 17, 2025

(30) Foreign Application Priority Data
Mar. 25, 2024 (CN) 202410349053.8

(51) Int. Cl. H01L 23/498; H01L 21/48; H01L 21/56; H01L 23/00; H01L 23/31; H01L 23/367; H01L 23/373; H01L 23/538; H01L 25/065

(52) U.S. Cl. CPC H01L 23/49838; H01L 21/4853; H01L 21/486; H01L 21/56; H01L 23/3128; H01L 23/367; H01L 23/3736; H01L 23/49816; H01L 23/5385; H01L 23/5389; H01L 24/16; H01L 24/29; H01L 24/32; H01L 24/73; H01L 25/0652; H01L 2224/16227; H01L 2224/29139; H01L 2224/32145; H01L 2224/32225; H01L 2224/73253; H01L 2924/37001

(57) ABSTRACT

Disclosed are double-sided stacked fan-out package structure and fabrication method thereof, the package structure comprising a substrate with vias; chips stacked in layers; an encapsulation material layer; redistribution layers disposed on the encapsulation material layer; a first conductive structure through which the chips on a first surface are electrically connected to the redistribution layer; and a second conductive structure extending through the thickness of the substrate. Some sections of the second conductive structure are disposed in some vias in the substrate, and the redistribution layers on the first surface and a second surface of the substrate are electrically connected via the second conductive structure. With the second conductive structure electrically connecting the chips on both surfaces of the substrate, it avoids forming through silicon vias in the chips, reducing packaging costs and improving packaging yield; and meanwhile avoids chip interconnections through carrier plates and wires, improving transmission efficiency.

### CROSS-REFERENCE TO RELATED APPLICATION

This application claims the priority of Chinese patent application No. 202410349053.8, filed on Mar. 25, 2024, which application is hereby incorporated herein by reference.

### FIELD

The present invention relates to the field of integrated circuit packaging technology, and more particularly to a double-sided stacked fan-out package structure and fabrication method thereof.

### BACKGROUND

With the advancement of technology, data transmission volumes are becoming increasingly vast, resulting in growing demands for higher memory capacity in electronic devices. Due to limitations in data access and transmission speeds, meeting the needs for high data transfer capabilities and large storage capacities requires memory with higher bandwidth and lower power consumption. In order to increase the bandwidth of the memory, the 3D stacked bonding packaging process is commonly used in the industry to fabricate the package structure of the memory chip.

In the 3D stacked bonding packaging process, chip stacking is a more common form of packaging, which stacks multiple chips by means of stacked bonding to form a chip package structure with higher interconnect density and performance. In the chip stacking packaging process, there are two common ways to realize the interconnection between the stacked chips: one is to bond the stacked chips layer by layer through the wires on all sides, such as the packaging process used in LPDDR; the other is to interconnect the stacked chips through TSV (through silicon via) technology, such as the packaging process used in HBM. However, chip interconnection through wire bonding is prone to long signal transmission delay and bandwidth limitation due to the long total length of wires and carrier plate lines. This bonding method is costly and has poor heat dissipation. In contrast, chip interconnection via TSV technology requires the fabrication of silicon vias and copper pillars on the chip, which is a complex process with low packaging yields. TSV-based packaging process also demands expensive materials such as NCF (non-conductive film) or NCP (non-conductive paste), as well as TCB bonder (thermocompression debonding equipment), leading to very high process costs. Moreover, the bonding speed of chip stacking is extremely slow, resulting in low overall packaging efficiency.

### SUMMARY

Embodiments of the present invention provide a new three-dimensional stacked fan-out packaging scheme that does not require fabrication of TSV vertical interconnects, and does not require wires and carrier plate lines, and thus is able to further reduce the packaging costs and improve the packaging yields while ensuring higher interconnect density and transmission performance.

In a first aspect, embodiments of the present invention provide a double-sided stacked fan-out package structure comprising:
a substrate provided with through-vias and having a first surface and a second surface provided with stacked chips;
an encapsulation material layer filling at least a portion of the through-vias and encapsulating the chips and the substrate;
redistribution layers disposed on the encapsulation material layer and electrically connected to the chips;
a first conductive structure disposed in the encapsulation material layer on the first surface, the chips on the first surface being electrically connected to the redistribution layer on the first surface via the first conductive structure;
a second conductive structure extending through the thickness of the substrate and having at least a portion of sections provided in at least a portion of the vias of the substrate, wherein the redistribution layers on the first surface and the second surface of the substrate are electrically connected through the second conductive structure;
package external pin pads disposed on the redistribution layer on the first surface of the substrate and electrically connected to the redistribution layer; and
BGA solder balls or solder chip pin bumps disposed on and electrically connected to the package external pin pads.

In a second aspect, embodiments of the present invention provide a method of fabricating a double-sided stacked fan-out package structure comprising:
mounting at least one layer of chips by means of stacking of layers to regions on a first surface and a second surface of a substrate for mounting the chips, respectively, the substrate having vias extending through the thickness of the substrate;
covering chips mounted on one surface of the substrate with a protective layer;
encapsulating a side of the substrate away from the protective layer with an encapsulation material, wherein the encapsulation material is able to flow through the vias to a side of the substrate provided with the protective layer during the encapsulating, so as to encapsulate the chips mounted on both surfaces of the substrate at the same time through a single encapsulation process, and after the single encapsulation process, encapsulating the substrate and the chips mounted on the both surfaces with the encapsulation material except for surfaces of the chips covered by the protective layer, and the vias of the substrate are also filled with the encapsulation material;
fabricating conductive structures on the encapsulation material, including a first conductive structure disposed in a layer of the encapsulation material on the first surface and electrically conductive to the chips mounted on the first surface, and a second conductive structure disposed in the encapsulation material of the through-vias and extending through the thickness of the substrate;
removing the protective layer to expose the surfaces of the chips covered by the protective layer to a surface of the encapsulation material;
fabricating redistribution layers on the surface of the encapsulation material, which are electrically connected to the mounted chips via the conductive structures, wherein the redistribution layers on the first and second surfaces of the substrate are electrically connected via the second conductive structure;
fabricating package external pin pads on the redistribution layer on the first surface of the substrate, which are electrically connected to the redistribution layer; and
fabricating BGA solder balls or solder chip pin bumps on the package external pin pads.

In a third aspect, embodiments of the present invention provide another method of fabricating a package structure comprising:
fabricating a first via and a second via in a substrate, and fabricating a conductive pillar in the first via;
mounting at least one layer of chips by means of stacking of layers to regions on a first surface and a second surface of the substrate for mounting the chips, respectively;
covering chips mounted on one surface of the substrate with a protective layer;
encapsulating a side of the substrate away from the protective layer with an encapsulation material, wherein during the encapsulating, the encapsulation material is able to flow through the second via to a side of the substrate where the protective layer is located, so as to encapsulate the chips mounted on both surfaces of the substrate at the same time through a single encapsulation process, and after the single encapsulation process, encapsulating the substrate and the chips mounted on the both surfaces with the encapsulation material except for surfaces of the chips covered by the protective layer, and the second via of the substrate is also filled with the encapsulation material;
removing the protective layer to expose the surfaces of the chips covered by the protective layer to a surface of the encapsulation material;
fabricating conductive structures on the encapsulation material, including a first conductive structure disposed in a layer of the encapsulation material on the first surface and electrically conductive to the chips mounted on the first surface, and a second conductive structure extending through the thickness of the substrate, wherein the second conductive structure includes a conductive pillar section located in the first via and an interconnection line section located in the layer of the encapsulation material and electrically conductive to the corresponding conductive pillar section;
fabricating redistribution layers on the surface of the encapsulation material, which are electrically connected to the mounted chips via the conductive structures, wherein the redistribution layers on the first surface and the second surface of the substrate are electrically connected through the second conductive structure;
fabricating package external pin pads on the redistribution layer on the first surface of the substrate, which are electrically conductive to the redistribution layer; and
fabricating BGA solder balls or solder chip pin bumps on the package external pin pads.

The beneficial effect of the embodiments of the present invention is that in the solution provided by the embodiments of the present invention, the stacked chips are disposed on both the first surface and the second surface of the substrate, which reduces the substrate warpage caused by single-sided mounting during the fabrication process, and improves the encapsulation yields of the package structure and the stability of the structure. In the solution of the embodiments of the present invention, the chips mounted on both surfaces of the substrate are electrically connected by the second conductive structure disposed on the substrate and extending through the thickness of the substrate, i.e., the second conductive structure is directly and completely fabricated in the encapsulation material of the vias in the substrate (as described above in the second aspect of the fabrication method), or the second conductive structure includes a conductive pillar section fabricated in the first via in the substrate and an interconnecting line section fabricated in the encapsulation material (as described above in the third aspect of the fabrication method). As a result, compared with the existing TSV packaging process, the fabrication of vertical interconnecting conductive channels of through silicon vias on the chip by the TSV technology is avoided, the package costs are reduced, and the package yields can be effectively improved. Compared with the existing wire bonding packaging process, chip interconnections via the carrier plate and wires are avoided, data transmission time is shortened, and the transmission efficiency of the package structure is improved. Moreover, the embodiments of the present invention provide vias in the substrate and cover one side of the substrate with a protective layer, enabling simultaneous double-sided encapsulation from the other side. As a result, in the embodiments of the present invention, the substrate is tightly fixed in the package structure as a permanent substrate through the layer of encapsulation material, so that it is no longer necessary to peel off the substrate in the subsequent process. The substrate can provide support with better mechanical strength for the package structure, which further ensures the reliability of the package structure and simplifies the packaging process steps. At the same time, because the substrate in the embodiments of the present invention is the permanent substrate, the stacked chips in the embodiments of the present invention are directly mounted on the both surfaces of the substrate. As a result, the solution of the embodiments of the present invention also avoids the use of expensive materials such as NCF or NCP for filling and the use of expensive TCB equipment for debonding, which further simplifies the packaging process steps and reduces the package costs. In addition, since the package structure fabricated by the embodiments of the present invention by means of three-dimensional stacked layer stacking can be used to integrate the required chips according to the demands (including chip functions and number of chips), and the high-density interconnection between the chips can be realized by means of the first and the second conductive structures and the redistribution layers, the fabrication costs are low, the fabricated package structure has a higher transmission bandwidth and transmission rate, and it can be widely used in the memory. In the embodiments of the present invention, there are only vias or vertical interconnect conductive pillars in the substrate, and there is no need to fabricate interconnection lines, so the process is simple and cost-effective compared to the substrate for wire bonding package (which contains fine interconnection lines). Because of these features of the substrate of the embodiments of the present invention, in the preferred embodiments, the substrate of the embodiments of the present invention can also be fabricated using thicker thermally conductive materials such as metals (copper, aluminum, etc.), ceramics (alumina, aluminum nitride, silicon carbide, etc.), and composite materials (various types of double sided copper-clad laminates used in the printed wiring board industry, etc.), which provide a better heat dissipation than the HBM package and wire bonding package processes. In addition, conventional packaging, HBM or wire bonding processes usually require separate encapsulation for both sides. In this encapsulation method, after encapsulation on one side, the warpage of the package structure will be very large, which will easily lead to the inability to carry out the subsequent process, and may even lead to the inability to carry out the next encapsulation. In contrast, the fabrication process of the embodiments of the present invention uses a protective layer to protect one side of the chip, and combined with the design of the vias, the solution of the embodiments of the present invention realizes a simultaneous double-sided encapsulation on the other side, i.e., the encapsulation on both sides can be completed at the same time by encapsulating only once on the other side. As a result, there is basically no substrate warping problem after encapsulation, which reduces the difficulty and cost of the subsequent process. In addition, the fabrication process of the embodiments of the present invention also avoids the use of the expensive temporary bonding materials and temporary bonding carrier plates used in the HBM encapsulation process, which helps to reduce the costs.

### BRIEF DESCRIPTION OF THE DRAWINGS

In order to illustrate more clearly the technical solutions of the embodiments of the present invention, the drawings used in the description of the embodiments will be briefly described below. Obviously, the drawings are only some embodiments of the present invention. Other drawings may be obtained by a person of ordinary skill in the art without creative labor based on these drawings.

FIG. 1 schematically illustrates a vertical cross-sectional view of a double-sided stacked fan-out package structure of an embodiment of the present invention;

FIG. 2 schematically illustrates a vertical cross-sectional view of a double-sided stacked fan-out package structure of another embodiment of the present invention;

FIG. 3 schematically illustrates a vertical cross-sectional view of a double-sided stacked fan-out package structure of yet another embodiment of the present invention;

FIG. 4 schematically illustrates a vertical cross-sectional view of a double-sided stacked fan-out package structure of a further embodiment of the present invention;

FIG. 5 schematically illustrates a top view of a substrate used in the package structure illustrated in FIG. 4 of an embodiment of the present invention;

FIG. 6 schematically illustrates a vertical cross-sectional view of a three-dimensional stacked fan-out package structure of an embodiment of the present invention;

FIG. 7 schematically illustrates a flowchart of a method of fabricating the package structure illustrated in FIG. 1 of an embodiment of the present invention;

FIG. 8 schematically illustrates a vertical cross-sectional view of a chip structure prior to fabrication of a pin bump of an embodiment of the present invention;

FIG. 9 schematically illustrates a vertical cross-sectional view of a chip structure after fabrication of a pin bump of an embodiment of the present invention;

FIG. 10 schematically illustrates a vertical cross-sectional view of a chip structure prior to fabrication of a pin bump of an embodiment of the present invention;

FIG. 11 schematically illustrates a vertical cross-sectional view of a chip structure after fabrication of a pin bump of an embodiment of the present invention;

FIG. 12 schematically illustrates a vertical cross-sectional view of a substrate after fabrication of a via in the substrate of an embodiment of the present invention;

FIG. 13 schematically illustrates a vertical cross-sectional view of a package structure after double-sided chip mounting on a substrate of an embodiment of the present invention;

FIG. 14 schematically illustrates a vertical cross-sectional view of a package structure after covering a chip on one side of a substrate with a protective layer of an embodiment of the present invention;

FIG. 15 schematically illustrates a vertical cross-sectional view of a package structure after encapsulation of an embodiment of the present invention;

FIG. 16 schematically illustrates a vertical cross-sectional view of a package structure after fabrication of blind and through holes of an embodiment of the present invention;

FIG. 17 schematically illustrates a vertical cross-sectional view of a package structure after removal of the protective layer of an embodiment of the present invention;

FIG. 18 schematically illustrates a vertical cross-sectional view of a package structure after fabrication of redistribution layers and package external pin pads of an embodiment of the present invention;

FIG. 19 schematically illustrates a vertical sectional view of a package structure after fabrication of BGA solder balls of an embodiment of the present invention;

FIG. 20 schematically illustrates a flowchart of a method of fabricating a double-sided stacked fan-out package structure of another embodiment of the present invention;

FIG. 21 schematically illustrates a vertical cross-sectional view of a substrate of some embodiments;

FIG. 22 schematically illustrates a vertical cross-sectional view of a package structure after mounting of a chip on a substrate of some embodiments;

FIG. 23 schematically illustrates a vertical cross-sectional view of a package structure after covering a chip on one side of a substrate with a protective layer of yet another embodiment of the present invention;

FIG. 24 schematically illustrates a vertical cross-sectional view of a package structure after encapsulation of some embodiments;

FIG. 25 schematically illustrates a flowchart of a method of fabricating a double-sided stacked fan-out package structure of yet another embodiment of the present invention;

FIG. 26 schematically illustrates a vertical cross-sectional view of a package structure after covering a chip on one side of a substrate with a protective layer of a further embodiment of the present invention;

FIG. 27 schematically illustrates a vertical cross-sectional view of a package structure after removal of the protective layer of a further embodiment of the present invention;

FIG. 28 schematically illustrates a vertical cross-sectional view of a package structure after fabrication of a third conductive structure of an embodiment of the present invention;

FIG. 29 schematically illustrates a flowchart of a method of fabricating a double-sided stacked fan-out package structure of another embodiment of the present invention;

FIG. 30 schematically illustrates a vertical cross-sectional view of a substrate of some embodiments;

FIG. 31 schematically illustrates a vertical cross-sectional view of a package structure obtained by covering a chip on one side of a substrate with a protective layer of a further embodiment of the present invention;

FIG. 32 schematically illustrates a vertical cross-sectional view of a package structure after fabrication of a conductive structure of a further embodiment of the present invention;

FIG. 33 schematically illustrates a vertical cross-sectional view of a substrate of some embodiments.

### DETAILED DESCRIPTION

In order to make the objects, technical solutions and advantages of the embodiments of the present invention clearer, the technical solutions of the embodiments of the present invention will be described specifically in the following in connection with the drawings. Obviously, these embodiments are some, but not all, of the embodiments of the present invention. Based on the embodiments in the present invention, all other embodiments obtained by a person skilled in the art without creative labor fall within the scope of protection of the present invention.

It is noted that the embodiments and features in the embodiments in the present application may be combined with each other without conflict.

It should also be noted that the terms used in this application are generally those commonly used by those skilled in the art, and in the event of any inconsistency with commonly used terms, the terms used in this application shall prevail.

Finally, it should also be noted that in this application, relational terms such as first and second, etc., are used only to distinguish one entity or operation from another, and do not necessarily require or imply the existence of any such actual relationship or order between these entities or operations. It should be understood that such terms can be used interchangeably in appropriate contexts, serving only as a means to distinguish objects with similar attributes in the descriptions of the embodiments of the present application. Moreover, the terms “including” and “comprising” include not only those elements, but also other elements that are not expressly listed, or that are inherent in such processes, methods, articles, or devices. Unless otherwise restricted, elements defined by the phrase “comprising . . . ” do not exclude the presence of other identical elements in the processes, methods, articles, or devices that include said elements. The specific meaning of the above terms in the present invention may be understood by a person of ordinary skill in the art according to the specific circumstances.

As used herein, the term “chip” refers to any type of semiconductor chip or integrated circuit chip that realizes a specific function, as well as any type of semiconductor die or integrated circuit die that realizes a specific function, which can be a single-layer chip or a vertically interconnected stacked chip.

As used herein, the term “functional surface” refers to the surface of the chip on which the pin pads are provided, and the term “non-functional surface” refers to another surface opposite to the functional surface.

As used herein, the term “first surface” is used to describe only the surface of the substrate facing the side of the package pin pad, and the term “second surface” is used to describe only the surface of the substrate facing away from the package pin pad. Thus, it can be understood that when the position of the package pin pad changed, the position referred to by the first surface changes accordingly. Therefore, the “first surface” should not be limited to a specific surface shown in the drawings.

As used herein, the term “bottom chip” refers to the layer of chips in direct contact with the region of the substrate for mounting chips. The term “top chip” refers to the layer of chips stacked in a direction away from the surface of the substrate that is furthest away from the corresponding surface of the substrate. The term “upper chip” refers to the layer of chips stacked in a direction away from the substrate that is located between the bottom chip and the top chip, which can refer to either the layer of chips directly mounted on the bottom chip or the layer of chips mounted on a certain upper chip. Taking a certain surface of the substrate such as a first surface stacked with four layers of chips as an example, the bottom chips on the surface refer to the first layer of chips in contact with the surface of the substrate, the uppermost chips refer to the fourth layer of chips furthest away from the surface of the substrate, and the upper chips can refer to any layer of chips between the first layer of chips and the fourth layer of chips.

As used herein, the term “bottom” refers to a direction toward the surface of the substrate, while “top” refers to a direction away from the surface of the substrate.

By leveraging advanced packaging technologies to assemble individually designed computing units or functional units, it is possible not only to ensure the yield of each unit by selecting the most suitable semiconductor process for each but also to effectively reduce the design and manufacturing costs of chips and shorten their development cycles. Three-dimensional stacked packaging technology has garnered significant attention due to its ability to provide integrated chips with high interconnection density, high performance, low power consumption, and high data transmission rates. However, current 3D stacked packaging processes primarily rely on TSV interconnection and wire bonding technologies to interconnect stacked chips. Both TSV and wire bonding techniques have drawbacks, such as high complexity and cost in the packaging process. Moreover, TSV interconnection techniques result in low packaging yields, while wire bonding techniques can lead to reduced transmission rates. To address these issues, the embodiments of the present invention aim to provide a novel 3D stacked packaging solution, which seeks to achieve high chip interconnection density and integration, as well as high data transmission rates, while simultaneously reducing packaging costs, improving packaging yields, and simplifying the packaging process.

The following will detail the solution provided by the embodiments of the present invention from the perspective of the construction of the package structure.

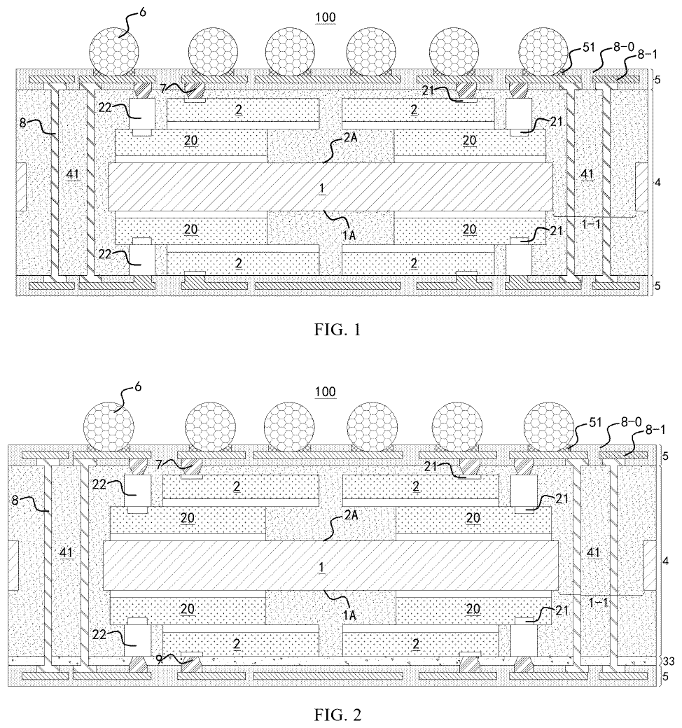

FIG. 1 schematically illustrates a vertical cross-sectional view of a double-sided stacked fan-out package structure 100 of an embodiment of the present invention. As shown in FIG. 1, the package structure 100 provided in an embodiment of the present invention comprises a substrate 1, chips 2 stacked on each other and mounted on a first surface 2A and a second surface 1A of the substrate 1, respectively, an encapsulation material layer 4 encapsulating the substrate 1 and the chips 2, redistribution layers 5 disposed on the encapsulation material layer 4, package external pin pads 51 disposed on the redistribution layer 5, and solder balls 6 disposed on the package external pin pads 51. The functional surface of the chip 2 is provided with pin pads 21, and in a preferred embodiment, pin bumps may be provided on at least part of the pin pads 21 of at least part of the chips 2 for electrical connection of the corresponding chips, in particular for electrical connection of layers of chips other than the uppermost chip, such as the bottom chip and the upper chip, to the redistribution layer. As shown in FIG. 1, in this embodiment, each surface of the substrate carries two layers of stacked chips. Pin bumps 22 are disposed on certain pin pads of the bottom chip 20, enabling the bottom chip 20 to be electrically conductive to the redistribution layer 5 via the pin bumps 22. This allows the bottom chip 20 to achieve external electrical connection through the redistribution layer 5 and package external pin pads 51. The redistribution layer 5 comprises an insulating material 8-0 and package interconnection lines 8-1 formed in the insulating material 8-0. The package interconnection line is electrically connected to the pin bumps 22 and/or the pin pads 21 of the chip via a conductive structure. The package external pin pad 51 is disposed on the surface of the insulating material 8-0 and is electrically connected to at least a portion of the conductive structure through the package interconnection lines 8-1 of the redistribution layer. Thus, the package external pin pad 51 can be electrically connected to the pin bumps 22 and/or the pin pads 21 of the chip via the package interconnection lines and the conductive structure. The solder balls 6 are provided on the package external pin pads 51 to realize electrical conduction with the chips via the package external pin pads 51. In the package structure 100 of the embodiment of the present invention, as shown in FIG. 1, the conductive structure comprises a first conductive structure 7 in the encapsulation material layer 4 disposed on the first surface 2A, and a second conductive structure 8 extending through the thickness of the substrate. The chip 2 disposed on the first surface 2A is electrically connected to the package interconnection line 8-1 in the redistribution layer 5 on the first surface 2A via the first conductive structure. The package interconnection lines 8-1 in the redistribution layers on the first surface 2A and the second surface 1A of the substrate are electrically connected via the second conductive structure 8. As a possible embodiment, as shown in FIG. 1, the chip 2 disposed on the second surface 1A may be directly electrically connected to the package interconnection line in the redistribution layer 5 on the second surface 1A. As a result, the chip on the first surface of the substrate of the embodiment of the present invention can then be electrically connected to the package external pin pads through the first conductive structure and the redistribution layer, and the chip on the second surface of the substrate can be electrically connected to the package external pin pads through the redistribution layer and the second conductive structure, so as to electrically connect the chips stacked on both surfaces of the substrate with the outside, and to electrically connect the chips stacked on the both surfaces of the substrate as well. Therefore, the stacked chips are used to provide desired functionality for application scenarios, such as storage capacity, computing capacity, and data transmission capacity. Since this type of package structure does not require the formation of through-silicon vias within the chips or the use of wires and carrier plates for chip interconnection, it achieves higher data transmission rates and packaging yields while lowering packaging costs. Furthermore, the inclusion of a substrate for structural support enhances the overall mechanical strength of the package structure. With the ability to package on both surfaces of the substrate, this configuration enables higher chip integration density.

As a possible embodiment, as shown in FIG. 1, the second conductive structure 8 of the substrate 1 is provided in the encapsulation material 41 of the vias 1-1 of the substrate. In this embodiment, each via in the substrate is used as both a flow channel for the encapsulation material and a fabrication channel for the second conductive structure. Thus, all vias 1-1 in the substrate of this embodiment are filled with the encapsulation material 41 of the encapsulation material layer 4. The second conductive structure 8 can be provided in the encapsulation material of each via to reduce the fabrication cost of the second conductive structure and to improve the encapsulation yield. Specifically, the vias 1-1 provided in the substrate 1 are vias that penetrate the substrate 1 along its thickness, forming fluid communication between the two surfaces of the substrate. This arrangement of the vias 1-1 allows the encapsulation material layer 4 in the package structure 100 of the embodiments of the present invention to be fabricated in a single step on one side of the substrate 1. That is, through this single encapsulation process, both sides of the substrate can be encapsulated simultaneously, simplifying the packaging process, lowering the fabrication cost of the package structure 100, and ensuring its reliability.

FIG. 2 schematically illustrates a double-sided stacked fan-out package structure of another embodiment of the present invention. As shown in FIG. 2, it is distinguished from the package structure shown in FIG. 1 in that the package structure further comprises an insulating material layer 33 disposed on the second surface 1A of the substrate 1 and a third conductive structure 9 disposed in the insulating material layer 33. The insulating material layer 33 is disposed on the encapsulation material layer 4 on the second surface 1A, and the redistribution layer 5 on the second surface 1A is disposed on the insulating material layer 33. Thus, in the embodiment of the present invention, the chip 2 disposed on the second surface 1A is electrically connected to the redistribution layer 5 on the second surface 1A via the third conductive structure 9. That is, in the embodiment shown in FIG. 1, the encapsulation material layer 4 on the second surface 1A is flush with the upper surface of the uppermost chip on the second surface, the redistribution layer 5 is provided directly on the encapsulation material layer 4, and the chip on the second surface 1A is directly electrically connected to the package interconnection lines of the redistribution layer 5 provided on the second surface through its pin pads or pin bumps. In the embodiment shown in FIG. 2, on the other hand, the insulating material layer 33 on the second surface 1A completely encapsulates the uppermost chip on the second surface, and thus the pin pads or pin bumps of the chip on the second surface 1A are electrically connected to the package interconnection lines of the redistribution layer 5 provided on the second surface through the third conductive structure 9. It should be noted that in this embodiment, the second conductive structure runs through both the encapsulation material layer 4 and the insulating material layer 33.

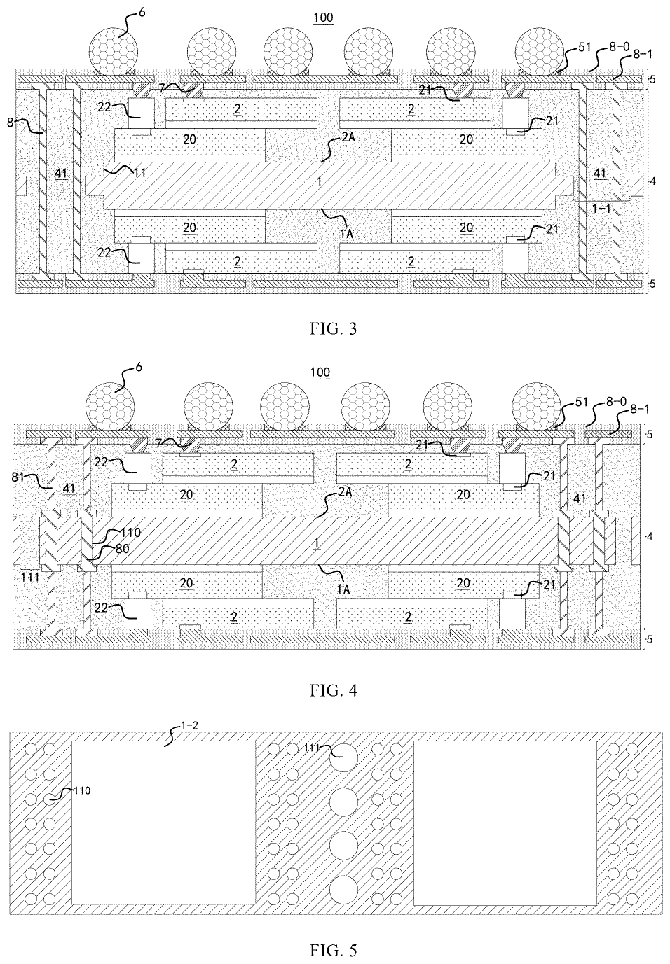

FIG. 3 schematically illustrates a double-sided stacked fan-out package structure of another embodiment of the present invention. As shown in FIG. 3, it differs from the package structure shown in FIG. 1 in that the substrate 1 is also provided with a step structure 11 that is lower than the region used for mounting the chip, thereby allowing the encapsulation material to be more securely fixed around the vias to improve the reliability of the package structure. In other embodiments, the step structure may also be provided to be higher than the region used for mounting the chip, and the region on the substrate used for mounting the chip is designed as a recessed structure to facilitate fast mounting of the chip and reduce the size of the package structure.

FIG. 4 schematically illustrates a double-sided stacked fan-out package structure of yet another embodiment of the present invention. As shown in FIG. 4, it differs from the package structure shown in FIG. 1 in that the vias in the substrate include a first via 110 for use as a fabrication channel of the second conductive structure and a second via 111 for use as a flow channel of the encapsulation material. This embodiment illustrates two types of vias in the substrate, one type of which possesses an electrical connecting function while the other type of which does not. The second conductive structure 8 comprises a conductive pillar section 80 disposed in the first via 110 and an interconnection line section 81 electrically connected to the corresponding conductive pillar section 80 and disposed in the encapsulation material layer 4. The first via 110 is filled with the conductive pillar section 80 of the second conductive structure, and the second via 111 is filled with encapsulation material of the encapsulation material layer 4.

Preferably, FIG. 5 illustrates a top view of the substrate used in the package structure shown in FIG. 4. As shown in FIG. 5, in the structure of the package structure shown in FIG. 4, the diameter of the first via 110 is smaller than the diameter of the second via 111, and the number and density of the first vias 110 are larger than the number and density of the second vias 111. Since in the package structure shown in FIG. 1, the second conductive structure is provided in the encapsulation material of the via 1-1, it is deeper and difficult to fill with the conductive material. This requires that the ratio of the depth to the diameter of the second conductive structure not be too large, thereby limiting the number and density of the second conductive structures. Moreover, in order to take into account the encapsulation efficiency and the support firmness of the substrate, the diameter of the via 1-1 provided in the substrate needs to be relatively large and the density cannot be too high, which further limits the number and density of the second conductive structures. As a result, in the embodiment of FIG. 1, the density of the second conductive structures cannot be very high, which to a certain extent affects the interconnection density of the package structure.

In the embodiment shown in FIG. 4, the second conductive structure is divided into the conductive pillar section 80 and the interconnection line section 81. The conductive pillar section 80 is provided in the first via, and the interconnection line section 81 is provided in the encapsulation material. Thus, it is possible to fabricate the conductive pillar section 80 of the second conductive structure in advance prior to encapsulation, thereby separating the role of the vias. That is, by separating the vias used as the flow channel of the encapsulation material from the vias used as the channel of the conductive structure, it is possible to fabricate the first vias of smaller aperture diameter and higher density in the substrate as channels for the electrically conductive interconnections. Furthermore, by dividing the second conductive structure into sections, the depth of the interconnection line section fabricated in the encapsulation material can be reduced, thereby eliminating the limitation on the density of the second conductive structures due to the ratio of the depth to diameter of the second conductive structure. As a result, the density of the second conductive structures can be further effectively increased to achieve the effect of increasing the interconnection density of the package structure. As can be seen from the embodiment of FIG. 4, it is not necessarily to set the entire second conductive structure in the encapsulation material of the vias. As long as part of the sections is provided in at least part of the vias (i.e., only the conductive pillar section is provided in the first via) and part of the sections is provided in the encapsulation material (i.e., the interconnection line section is provided in the encapsulation material), the effect of electrically connecting the redistribution layers on the first surface and the second surface can be equally realized, and the second conductive structure can also be fabricated with higher density.

As a preferred embodiment, as shown in FIG. 4, the interconnection line section electrically connected to the corresponding conductive pillar section, which is disposed in the encapsulation material layer, is coaxially electrically connected to the corresponding conductive pillar section, thereby shortening the transmission distance of the second conductive structure and improving its transmission efficiency.

Of course, it is not difficult for a person skilled in the art to understand that in optional embodiments of the present invention, it is possible to provide the vias in the substrate with two types, one type of which has an electrical connection function and the other type of which does not have the electrical connection function. Even the embodiment shown in FIG. 1 can be provided with two types of vias in the substrate, one type of which has the electrical connection function and the other type of which does not have the electrical connection function. In this case, the second conductive structure can still be provided in the manner shown in FIG. 1, with the difference being only that the second conductive structure can be fabricated only in the encapsulation material of a portion of the vias, while the second conductive structure will not be fabricated in the encapsulation material of another portion of the vias. Of course, in the embodiment shown in FIG. 1, it is also possible to fabricate the second conductive structure of the structure shown in FIG. 1 in all of the encapsulation material of the vias, so that all of the vias in the substrate become vias having the electrical connection function.

As a preferred embodiment, the substrate 1 in the embodiment of the present invention is a heat dissipation plate made of a thermally conductive material such as a metal-based alloy, a ceramic, graphene, or the like. Since the substrate of the embodiment of the present invention is provided with only vias or vertical interconnection conductive pillar structures, it is not necessary to fabricate interconnection lines on the substrate, and therefore, compared to the substrate for wire bonding package (containing fine over-layer interconnection lines), the process of the substrate of the embodiment of the present invention is simple and cost effective, and can be fabricated using a thicker thermally conductive material such as a metal (copper, aluminum, etc.), a ceramic (alumina, aluminum nitride, silicon carbide, etc.), composite materials (double-sided copper-clad laminates used in various printed wiring board industry, etc.), etc. Compared with the HBM package and wire bonding package processes, the substrate of the embodiment of the present invention using the thermally conductive material has a better heat dissipation effect, and thus can allow the package structure to have a more excellent heat dissipation performance. Moreover, the substrate of the embodiments of the present invention is used as a permanent substrate for the package structure (i.e., it does not need to be removed during the package process), and thus it can provide support and protection for the package structure, so as to make it possible to directly carry out chip mounting on both surfaces of the substrate, thereby improving the chip integration degree of the package structure.

As a possible embodiment, the chips in the package structure are mounted on the chip-mounting regions of the first and second surfaces of the substrate through attachment materials. The attachment materials are preferably thermally conductive materials such as metal alloy solder, silver paste, or nano-silver paste, to further improve the heat dissipation performance of the package structure.

In another possible embodiment, the chip-mounting regions on the first and second surfaces of the substrate are further provided with heat dissipation holes for chip-to-chip heat dissipation. These heat dissipation holes are not filled with encapsulation materials, thus serving as heat dissipation channels between the chips to further enhance the heat dissipation of the package structure. In a preferred embodiment, these heat dissipation holes can be further filled with thermally conductive materials such as copper to further improve the heat dissipation performance of the package structure.

In a preferred embodiment, the pin bumps on at least some of the pin pads of at least some chips have different heights. As a result, after these chips are mounted on the substrate, the free end surfaces of the pin bumps of the chips mounted on the same surface of the substrate are located in the same plane, facilitating the electrical connection between the chips and the package interconnection lines of the redistribution layer. Chips without pin bumps can also be mounted on the uppermost layer of the corresponding surface of the substrate, serving as the uppermost chips furthest from the corresponding surface of the substrate, while the heights of the pin bumps of other chips are designed such that after all the chips are mounted on the corresponding surface of the substrate, the free end surfaces of the pin bumps of the chips mounted on the same surface of the substrate align with the functional surface of the chip on the surface and furthest from the substrate (i.e., align with the functional surface of the uppermost chip on the respective surface). Thereby, this ensures consistent pin heights for the chips mounted on the corresponding surface of the substrate, allowing direct wiring on the pin pads and pin bumps of the chips after the protective layer is removed. Alternatively, it enables consistent depths and dimensions for the openings used as the first or third conductive structures fabricated on the encapsulation material layer, thus aligning all opening process parameters and conductive material filling processes. This approach simplifies the process, makes it easier to control, and reduces costs.

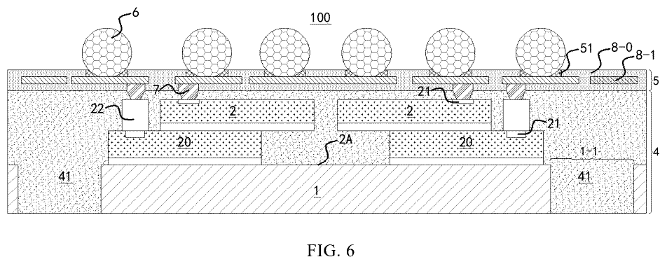

It should be noted that the above are merely some embodiments of the package structure in this invention. For those skilled in the art, it is not difficult to understand that certain features of the above package structure can be freely combined. For example, the substrate may or may not have a step structure provided thereon; the number of stacked chip layers on the substrate can be two, one, three, or more; the number of layers and functions of chips mounted on the first and second surfaces of the substrate can be identical or completely different; the chip-mounting regions on the substrate may or may not have heat dissipation holes provided therein, etc. Through such free combinations and variations, it is evidently possible to obtain more embodiments of the package structure, and these variations of the package structure should all fall within the protection scope of the present invention. Additionally, it should be noted that as another variation of the embodiment of this invention, the package structure adopting the above concept (i.e., a package structure that does not use TSV technology and wire bonding technology for chip interconnection) does not necessarily mount chips on both the first and second surfaces of the substrate. Instead, chips may be mounted on only one surface of the substrate to obtain a single-sided chip-mounted 3D stacked package structure. FIG. 6 illustrates a 3D stacked package structure obtained by mounting chips on a single side, where the chips mounted on one side of the substrate achieve electrical connection with package external pin pads only through the first conductive structure and redistribution layer.

The method of fabricating a package structure of the above structure will be described in detail below in conjunction with the drawings.

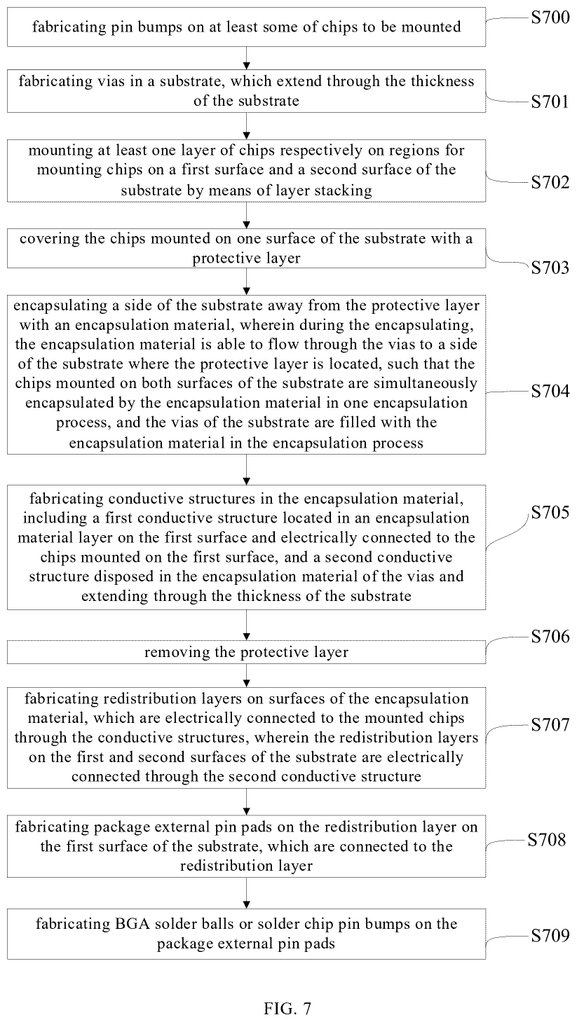

FIGS. 7 through 19 schematically illustrate a method of fabricating a package structure of the structure shown in FIG. 1. As shown in FIG. 7, the fabrication method comprises:
Step S700: fabricating pin bumps on at least some of chips to be mounted;
Step S701: fabricating vias in a substrate, which extend through the thickness of the substrate;
Step S702: mounting at least one layer of chips respectively on regions for mounting chips on a first surface and a second surface of the substrate by means of layer stacking;
Step S703: covering the chips mounted on one surface of the substrate with a protective layer;
Step S704: encapsulating a side of the substrate away from the protective layer with an encapsulation material. During encapsulating, the encapsulation material flows through the vias to the side of the substrate with the protective layer, encapsulating the chips mounted on both sides of the substrate in a single encapsulating step with the encapsulation material, while filling the vias in the substrate with the encapsulation material in the encapsulating process;
Step S705: fabricating conductive structures on the encapsulation material. The conductive structures include a first conductive structure electrically connected to the chips mounted on the first surface and disposed in the encapsulation material of the first surface, and a second conductive structure disposed in the encapsulation material of the vias and extending through the thickness of the substrate;
Step S706: removing the protective layer;
Step S707: fabricating redistribution layers on surfaces of the encapsulation material, which are electrically connected to the mounted chips via the conductive structures. The redistribution layers on the first surface and the second surface of the substrate are electrically connected through the second conductive structure;
Step S708: fabricating package external pin pads on the redistribution layer on the first surface of the substrate, which are electrically connected to the redistribution layer;
Step S709: fabricating BGA solder balls or solder chip pin bumps on the package external pin pads.

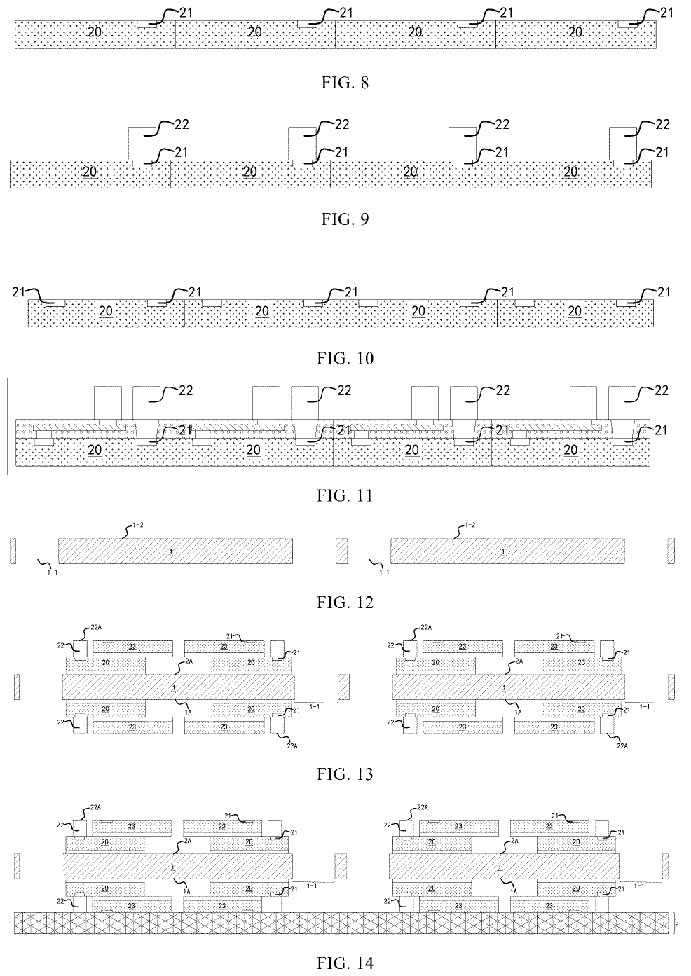

In step S700, the pin bumps are fabricated on the pin pads of the functional surface of the chips to establish electrical connections for the chips, such as between the chips and the redistribution layer or the first conductive structure. Therefore, the position where the pin bumps are fabricated can be selected as needed, and is not limited by the invention. It should be noted that in some embodiments, multiple chips may be stacked in multiple layers as needed. Therefore, to ensure that the chips at each layer can be conveniently electrically connected to the redistribution layer, the positions of the pin pads of the corresponding chips can be transferred and reset to the desired locations using RDL redistribution technology. When fabricating pin bumps on chips, they can be prepared on all chips or only on some of them. The present invention imposes no restrictions in this regard. For example, in the package structure shown in FIG. 1, pin bumps are fabricated only on the bottom chips, while the uppermost chips have no pin bumps. The uppermost chips are electrically connected to the redistribution layer via the first conductive structure and their pin pads. Taking the case where pin bumps are fabricated on all pin pads of the chips as an example, FIGS. 8 and 9 schematically illustrate cross-sectional views of the chips before and after the fabrication of pin bumps. As shown in FIG. 9, pin bumps 22 are fabricated on pin pads 21 of the chips 2. Due to the height of the pin bumps, electrical connections between the respective layer of chips and the redistribution layer can be conveniently achieved through the pin bumps 22. As another example, where RDL redistribution is required in advance on the chip to transfer the positions of the pin pads, FIGS. 10 and 11 illustrate cross-sectional views of the chips before and after the fabrication of pin bumps. The pin pads in FIG. 10 are the original pin pads on the chip. After redistribution, as shown in FIG. 11, new pin pads are added to the chip, and pin bumps 22 are fabricated on some of the pin pads 21 as needed. In practical applications, the pin bumps 22 can be metal pillar structures, such as micro-copper pillar structures.

In step S701, the substrate may be made of metal, ceramic, or composite thermally conductive materials. Vias can be fabricated in the substrate using laser drilling to serve as flow channels for the encapsulation material and channels for the second conductive structure. The positions and widths of the vias can be configured as needed. It should be noted that, before fabricating the vias, regions on the substrate must be reserved for chip mounting, and vias should be formed outside the chip mounting regions. In a preferred embodiment, heat dissipation holes may also be fabricated in the reserved chip mounting regions. FIG. 12 schematically illustrates a cross-sectional view of the substrate obtained after fabricating the vias in the substrate. As shown in FIG. 12, the substrate has chip mounting regions 1-2 and vias 1-1 formed thereon. In other embodiments, heat dissipation holes for chip cooling can also be formed in the chip mounting region 1-2 of the substrate. A top view of the resulting substrate is shown in FIG. 33. Square heat dissipation holes 121 are formed in the chip mounting regions 1-2. Since these holes are covered by mounted chips throughout the entire chip fabrication process, they will not be filled with encapsulation material. These holes can function as heat dissipation channels, providing excellent cooling performance for the mounted chips. Of course, the heat dissipation holes are not limited to a square shape but may also take other forms. The present invention imposes no restrictions in this regard.

In step S702, chips can be mounted on the substrate fabricated in step S701 by stacking them in layers using attachment materials. The chips are mounted in the chip mounting regions 1-2, with all functional surfaces of chips facing away from the substrate, ensuring that the pin bumps of the previously mounted chips remain exposed. Exemplarily, the attachment material can include thermally conductive adhesives such as metal alloy solder, silver paste, or nano-silver paste. The chips mounted on the substrate can form a single layer, two layers, or more. For example, in a two-layer double-sided mounting, the cross-sectional view of the structure after chip mounting is shown in FIG. 13. Two groups of stacked chips are mounted on both the first surface 2A and the second surface 1A of the substrate 1. Pin bumps 22 are fabricated on the bottom chips, while the uppermost chips have no pin bumps. The functional surfaces of the chips face upward, allowing electrical connections through the pin bumps or pin pads thereon. To facilitate the electrical connection of the bottom chips, as shown in FIG. 13, the free end surfaces 22A of the pin bumps 22 on the bottom chips 20 are aligned with the functional surface of the uppermost chips 23. Preferably, during chip mounting, attachment materials can be used to attach the non-functional surfaces of the bottom chips 20 to the chip mounting regions 2-2 of the substrate, while the upper chips are mounted with their functional surfaces facing upward on the functional surfaces of the chips below them. During mounting, the pin bumps on the functional surfaces of all layers of chips below the uppermost chips must remain exposed to facilitate electrical connections of all layers of chips. As shown in FIG. 13, the two layers of chips are offset-stacked. The pin bumps 22 on the bottom chips 20 are not covered or obscured by the chips above them. It is worth noting that if, due to the positioning of the pin pads on the chips, the pin bumps of the chips below the uppermost chips are likely to be obscured during stacked mounting, the positions of the pin pads on the respective chips can be adjusted through a redistribution process during fabricating the pin bumps in step S700, ensuring that the pin bumps of other chips below the uppermost chips remain exposed after mounting. In step S703, since the substrate includes vias, covering the chips mounted on one surface of the substrate with a protective layer allows for single-process dual-sided encapsulation from the other side. The protective layer can be a temporary carrier coated with a peelable material or a high-temperature-resistant protective film. When using a high-temperature-resistant protective film, its thickness can be set between 50-300 μm. Examples of the high-temperature-resistant protective film in the embodiment of the present invention includes PI or Teflon films coated with high-temperature-resistant adhesive film. Due to the improved overall process in the embodiment of the present invention, during encapsulating, the protective layer only needs to be vacuum-fixed in a fixed position within the encapsulation mold, eliminating the need for transfer or handling of the covered protective layer between precise processes. Thus, in the embodiment of the present invention, the protective layer does not use temporary bonding material and can instead use high-temperature-resistant protective films or peelable materials. Temporary bonding materials typically require pre-bonding to temporary carriers to prevent warping during precise processing steps, and they must withstand multiple high-temperature and acid-alkali processes in the temporary bonding. These requirements place high demands on the heat resistance, acid-alkali resistance, and adhesive properties of the temporary bonding material, as well as displacement control relative to the chips. Moreover, a dual-sided bonding is required, making the encapsulation protection through the temporary boding expensive. Compared to packaging with the temporary bonding method, the packaging method in the embodiment of the present invention only subjects the protective layer covering the chips to a single high-temperature process. The protective layer used to shield the chip surfaces during encapsulating does not need to be removed, and a single-sided covering suffices, significantly reducing packaging costs. Additionally, since the high-temperature-resistant protective film is already cured when applied to the mounted chips, it provides excellent fixation of the chips during encapsulating. This avoids the complications of encapsulating with the temporary bonding method where the temporary bonding material is easy to move and necessitate its placement on a carrier. FIG. 14 schematically illustrates the effect after covering the chips on one side of the substrate with a protective layer, wherein the protective layer 3 adheres to the uppermost chips. Since the free end surfaces of the pin bumps 22 on the bottom chips 20 are flush with the functional surfaces of the uppermost chips, the protective layer 3 adheres to both the functional surfaces of the uppermost chips and the pin bumps 22 of the bottom chips. In other embodiments, pin bumps can also be fabricated on the pin pads of the uppermost chips, with pin bumps of at least some of chips designed to have varying heights. This ensures that the pin bump heights of chips in different layers become consistent after mounting on the substrate. Specifically, the free end surfaces of the pin bumps on different layers of chips mounted on the same surface side will lie in the same plane, facilitating the subsequent fabrication of redistribution layers.

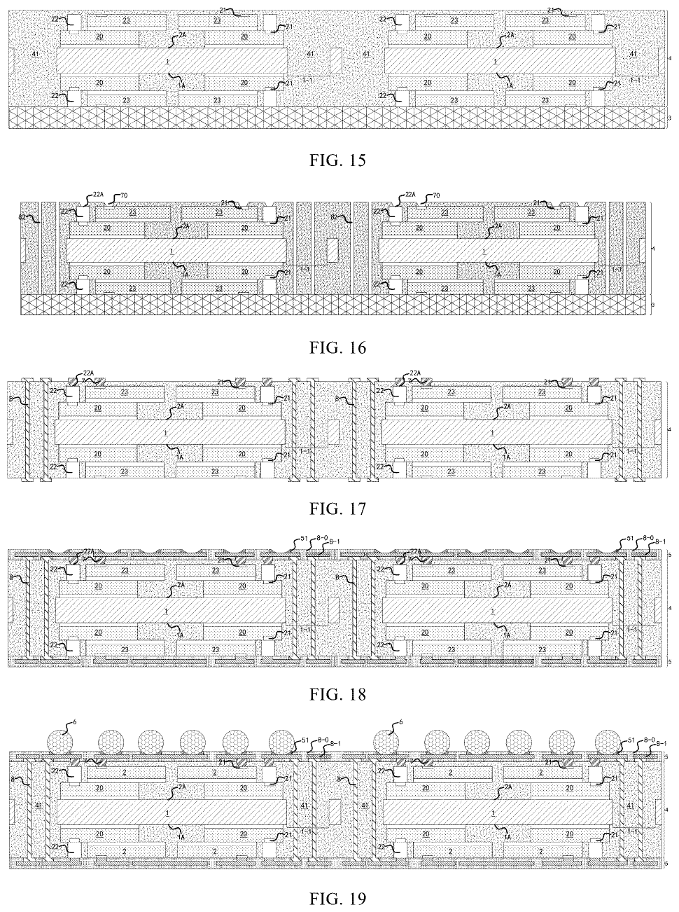

In step S704, the encapsulation is performed from the side away from the protective layer. Since the substrate is provided with vias, the encapsulation material flows from the side away from the protective layer through the vias to the other side of the substrate, achieving simultaneous encapsulation of both sides of the substrate in a single step and embedding the substrate within the package structure through encapsulating, thereby enhancing the mechanical strength of the structure. FIG. 15 illustrates the encapsulation result of one embodiment. As shown in FIG. 15, after encapsulation, the encapsulation material 41 fills the vias 1-1 of the substrate 2 and simultaneously encapsulates the chips mounted on both surfaces of the substrate and the substrate. On the side away from the protective layer, the encapsulation material completely covers the chips and substrate. On the side with the protective layer, the surface of the encapsulation material aligns flush with the functional surface of the uppermost chip mounted on that side.

In step S705, a hole structure may first be fabricated on the encapsulation material of the vias and on the encapsulation material layer of the first surface, respectively. Through holes can be fabricated in the encapsulation material of the vias, while blind holes can be fabricated on the encapsulation material layer of the first surface. The positions of the blind holes can correspond to the pin bumps and/or pin pads of the respective chips. Subsequently, conductive materials can be filled into the through holes and blind holes to form the respective conductive structures. Methods such as laser drilling, photolithography, or dry etching can be used to fabricate the through holes in the encapsulation material of the vias. The blind holes can be fabricated on the positions corresponding to the pin bumps and/or pin pads of chips by laser drilling, photolithography, dry etching, grinding, or the like. FIG. 16 illustrates the result after fabricating the through holes and blind holes. As shown in FIG. 16, through holes 82 are fabricated in the encapsulation material of the vias, penetrating the encapsulation material layer 4 in the thickness direction. Blind holes 70 corresponding to the pin bumps and pin pads of chips mounted on the first surface of the substrate are formed on the surface of the encapsulation material layer on the side away from the protective layer. Thus, by filling conductive materials into the through holes 82, the second conductive structure can be formed. By filling conductive materials into the blind holes 70, the first conductive structure can be formed. The chips mounted on the first surface of the substrate achieve electrical connection with the first conductive structure through their pin pads and pin bumps.

In step S706, depending on the characteristics of material selected for the protective layer, the protective layer may be removed by means compatible with its material characteristics. For example, the protective layer with corresponding characteristics may be removed by heat peeling, chemical peeling, laser peeling, UV light peeling, heat and mechanical force peeling, and the like. The cross-sectional view of the intermediate structure after removing the protective layer is shown in FIG. 17. The first conductive structure 7 is electrically connected to the pin pads and pin bumps 22 of the chips mounted on the first surface. The pin bumps 22 of the chips mounted on the second surface and the pin pads of the uppermost chips are exposed from the surface of the encapsulation material layer, while the second conductive structure 8 extends through the encapsulation material layer 4 on both sides of the substrate.

In step S707, redistribution layers can be fabricated on the surfaces of the encapsulation material layer on both sides of the substrate, respectively. The fabricated redistribution layers consist of insulating materials and package interconnection lines in the insulating materials. The package interconnection lines are electrically connected to the first conductive structure and the second conductive structure, respectively, as well as to the exposed pin bumps and pin pads of the chips on the second surface. Consequently, the redistribution layer on the first surface side can be electrically connected to the chips mounted on the first surface via the first conductive structure, and the redistribution layer on the second surface side can be directly connected to the chips mounted on the second surface via the package interconnection lines, pin pads and pin bumps of the chips. The redistribution layers on the first and second surfaces of the substrate can be electrically connected through the second conductive structure, enabling all chips mounted on the substrate to be electrically connected with the redistribution layers. In step S708, as needed, package external pin pads can be formed on certain package interconnection lines of the redistribution layer to electrically connect the chips to the outside via the package external pin pads. The package external pin pads can be fabricated on the redistribution layer on the first surface side. FIG. 18 illustrates a cross-sectional view of an intermediate structure provided with redistribution layers and package external pin pads. As shown in FIG. 18, the redistribution layers 5 consist of insulating material 8-0 and package interconnection lines 8-1 embedded therein. The package interconnection lines 8-1 of the redistribution layer 5 on the first surface 2A side are electrically connected to the chips mounted on the first surface via the first conductive structure 7. The package interconnection lines 8-1 of the redistribution layer 5 on the second surface 1A side are directly electrically connected to the pin pads or pin bumps 22 of the chips mounted on the second surface. The package interconnection lines 8-1 of the redistribution layers 5 on the first and second surfaces are also electrically connected through the second conductive structure 8. On certain package interconnection lines of the redistribution layer 5 on the first surface side, package external pin pads 51 are provided, which are electrically connected to the package interconnection lines, and to the respective chips through the redistribution layer 5, the first conductive structure 7, and the second conductive structure 8.

In step S709, the chips can be electrically connected to the outside via the BGA solder balls or the solder chip pin bumps by fabricating the BGA solder ball or the solder chip pin bumps on the package external pin pads, so as to realize the desired function. FIG. 19 illustrates a cross-sectional view of an intermediate structure provided with BGA solder balls. As shown in FIG. 19, BGA solder balls 6 are provided on the package external pin pads 51, and the BGA solder balls 6 are electrically connected to each chip through the package external pin pads 51, the redistribution layer 5, the first conductive structure 7 and the second conductive structure 8. In this example, two sets of stacked chips are mounted on the substrate; thus, it is also necessary to cut the resulting package structure to obtain individual package structures. A single package structure obtained by cutting the package structure shown in FIG. 19 is the package structure of the structure shown in FIG. 1. Of course, in the case where the chips mounted on the substrate constitute a single group or the package structure obtained is itself a single package structure, it is not necessary to carry out the cutting operation again, and the final usable package structure is obtained directly after the processing of step S709.

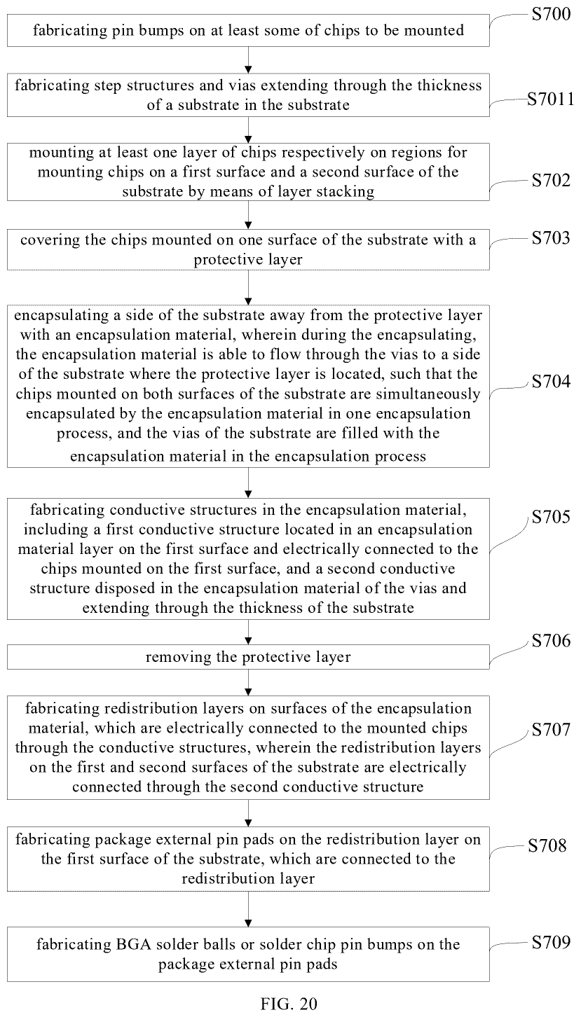

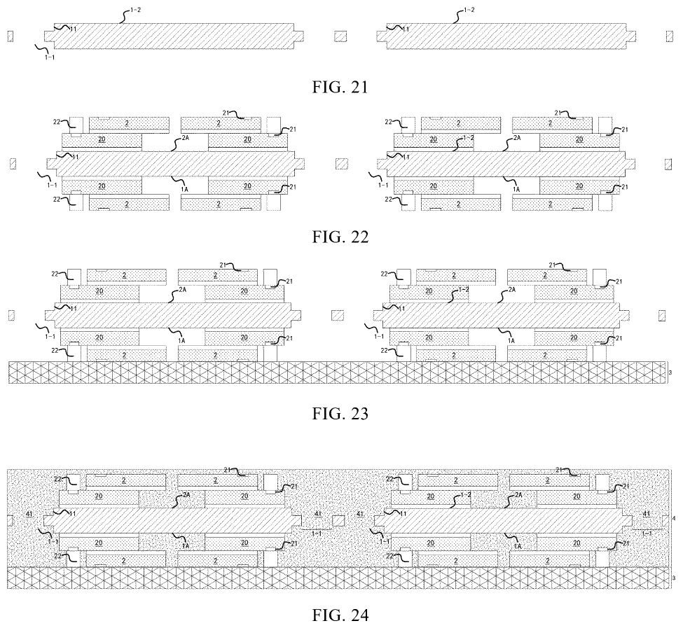

FIG. 20 schematically illustrates a fabrication method for the package structure of the structure shown in FIG. 3. As shown in FIG. 20, the fabrication method is essentially the same as that shown in FIG. 7, the only difference being that in step S7011, in addition to fabricating vias in the substrate in the direction of the thickness of the substrate, step structures are fabricated on the substrate, and the resulting intermediate structure is shown in FIG. 21. There are also step structures 11 below the surface of the mounting region 1-2 at the edge of the region 1-2 of the substrate for mounting the chips. The structure obtained after mounting the chips at step S702 is shown in FIG. 22, and the structure obtained after step S703 is shown in FIG. 23. The structure obtained after step S704 is shown in FIG. 24. The step structures 11 are encapsulated by the encapsulation material, thus enabling the mounted chips to be encapsulated more firmly. The structure of the package structure ultimately obtained after the complete processing of the fabrication method of FIG. 20 is shown in FIG. 3. The substrate includes the step structures 11, and the step structures 11 are filled and encapsulated by the encapsulation material in order to encapsulate the chips more firmly on the substrate.

It should be noted that the step structures fabricated on the substrate may be step structures raised relative to the region 1-2 used for mounting the chips or step structures recessed relative to the same. FIG. 3 is only an example of step structures recessed relative to the regions used for mounting the chips, and the person skilled in the art should understand that step structures recessed relative to the region 1-2 used for mounting the chips are feasible as well.

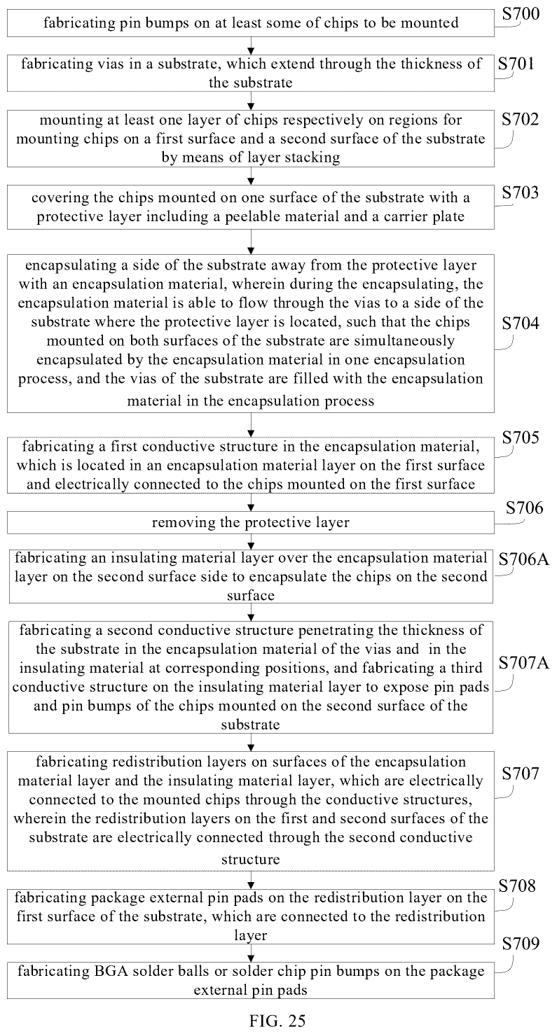

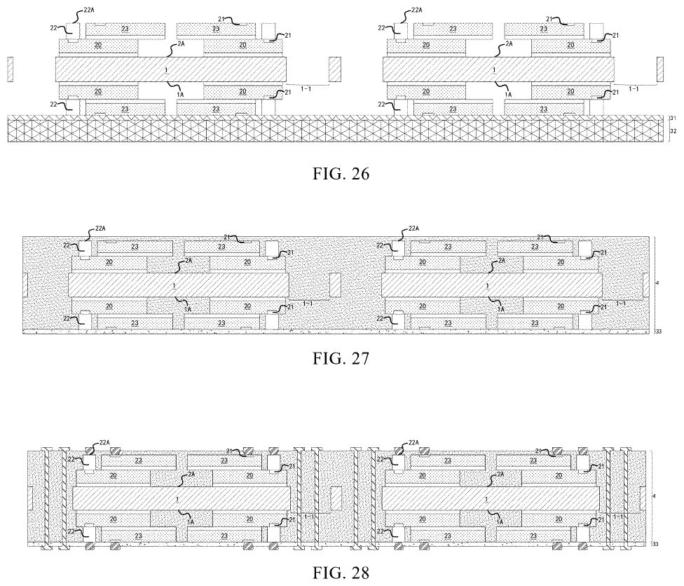

FIG. 25 schematically illustrates a method of fabricating a package structure of the structure shown in FIG. 2. As shown in FIG. 25, the fabrication method is essentially the same as the fabrication method shown in FIG. 7, the only difference being that the protective layer covered in step S703 includes a peelable material and a carrier plate. After peeling off the protective layer, an insulating material layer for encapsulating the chips on the second surface is further fabricated on the encapsulation material layer on the side where the protective layer was removed, forming the second encapsulation material layer. After fabricating the insulating material layer, the second conductive structure is patterned. The encapsulation material layer penetrated by the second conductive structure includes the insulating material layer, i.e., the second encapsulation material layer. Subsequently, the third conductive structure is also fabricated on the insulating material layer. The intermediate structure after step S703 is shown in FIG. 26. The protective layer consists of a peelable material layer 31 and a carrier plate 32. After removing the protective layer in step S706, an additional insulating material layer is further fabricated in step 706A on the second surface of the substrate as the second encapsulation material layer, covering the chips mounted on the second surface of the substrate. Thus, before step S707, step S707A is required to fabricate the third conductive structure on the insulating material layer to expose the pin pads and pin bumps of the chips mounted on the second surface of the substrate, enabling the electrical connection between the chips on the second surface and the redistribution layer. Therefore, in this embodiment, the intermediate structure after step S706A is shown in FIG. 27, including the insulating material layer 33 as the second encapsulation material layer. The intermediate structure after step S707A is shown in FIG. 28, where the second conductive structure penetrates both the encapsulation material layer 4 and the insulating material layer 33. The insulating material layer 33 also includes the third conductive structure 9, the fabrication method of which is the same as that of the first conductive structure, which can be referenced from the relevant description above and will not be elaborated here.

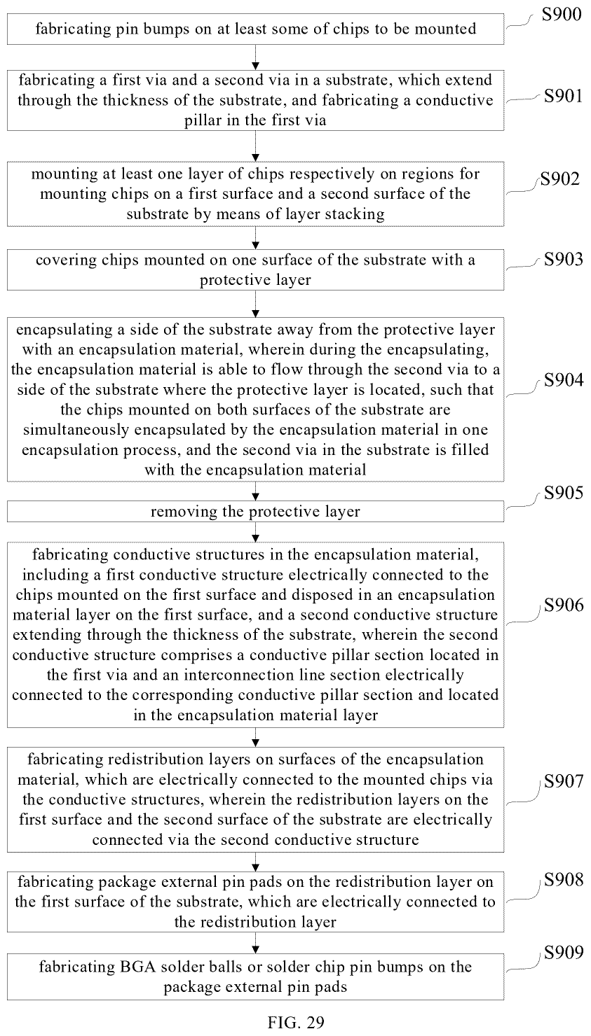

FIG. 29 schematically illustrates a method of fabricating a package structure of the structure shown in FIG. 4, comprising:
Step S900: fabricating pin bumps on at least some of chips to be mounted;
Step S901: fabricating a first via and a second via in a substrate, which extend through the thickness of the substrate, and fabricating a conductive pillar in the first via;
Step S902: mounting at least one layer of chips respectively on regions for mounting chips on a first surface and a second surface of the substrate by means of layer stacking;
Step S903: covering chips mounted on one surface of the substrate with a protective layer;
Step S904: encapsulating a side of the substrate away from the protective layer with an encapsulation material, wherein during the encapsulating, the encapsulation material is able to flow through the second via to a side of the substrate where the protective layer is located, such that the chips mounted on both surfaces of the substrate are simultaneously encapsulated by the encapsulation material in one encapsulation process, and the second via in the substrate is filled with the encapsulation material in the encapsulation process;
Step S905: removing the protective layer;
Step S906: fabricating conductive structures in the encapsulation material, including a first conductive structure electrically connected to the chips mounted on the first surface and disposed in an encapsulation material layer on the first surface, and a second conductive structure extending through the thickness of the substrate, wherein the second conductive structure comprises a conductive pillar section located in the first via and an interconnection line section electrically connected to the corresponding conductive pillar section and located in the encapsulation material layer;
Step S907: fabricating redistribution layers on surfaces of the encapsulation material, which are electrically connected to the mounted chips via the conductive structures, wherein the redistribution layers on the first surface and the second surface of the substrate are electrically connected via the second conductive structure;
Step S908: fabricating package external pin pads on the redistribution layer on the first surface of the substrate, which are electrically connected to the redistribution layer;
Step S909: fabricating BGA solder balls or solder chip pin bumps on the package external pin pads.

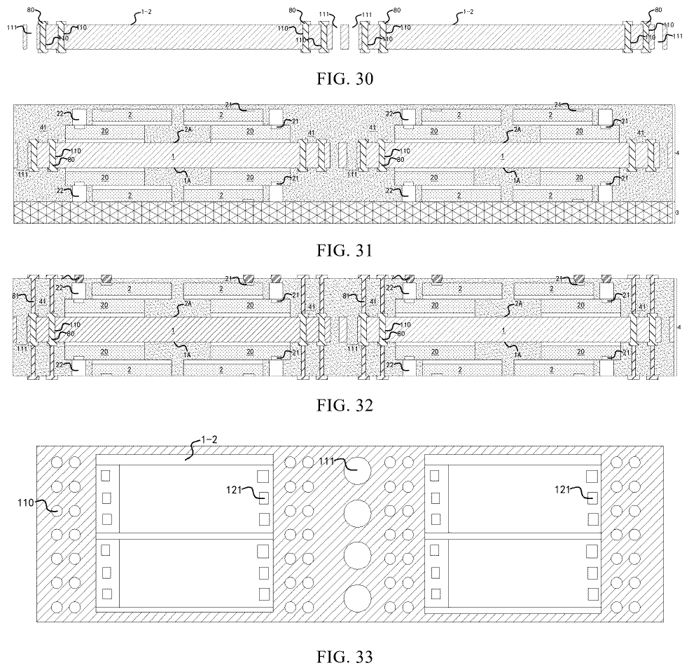

In the above fabrication method, the specific implementations of steps S900, S902, S903, S905, S907, S908, and S909 can all refer to the descriptions provided earlier. It should be noted that the protective layer in step S903 can either be the protective layer shown in FIG. 7 or the one shown in FIG. 25 (in this case, the second conductive structure is fabricated after the insulating material layer, and the interconnection line section on the second surface side simultaneously penetrates through the encapsulation material layer and the insulating material layer in the corresponding position). This embodiment of the invention does not impose restrictions on this aspect. The difference from the previously described method lies in step S901, where the vias fabricated in the substrate include two types: the second via, serving as a flow channel for the encapsulation material; and the first via, serving as a channel for the conductive structure. Additionally, the first via is filled with the conductive pillar in step S901. The substrate structure obtained from step S901 is as shown in FIGS. 5 and 30. FIG. 5 is a top view of the fabricated substrate, while FIG. 30 is a vertical cross-sectional view. The resulting substrate includes the first via 110 and the second via 111. The first via 110 has smaller diameters, higher density, and is filled with conductive pillar 80. In step S904, the encapsulation material flows through the second via to the other side of the substrate. Since the first via 110 is already filled with the conductive pillar, it is not filled with the encapsulation material. Taking the protective layer used in step S903, which includes a removable material layer and a carrier plate, as an example, the structure obtained after step S904 is shown in FIG. 31. The conductive pillar 80 in the first via 110 are completely encapsulated by the encapsulation material layer 4. Therefore, in this embodiment, when fabricating the conductive structure in step S906, a through hole is fabricated at the positions in the encapsulation material layer 4 corresponding to the conductive pillar 80, using methods such as laser drilling. Conductive material is then filled into the through hole to form the second conductive structure, which includes the conductive pillar section and interconnection line section. The cross-sectional view of the structure after step S906 is shown in FIG. 32. The second conductive structure includes the conductive pillar section 80 and the interconnection line section 81. The conductive pillar section 80 and the interconnection line section 81 are coaxially and electrically connected, jointly forming the second conductive structure 8, which penetrates through the substrate and the encapsulation material layer. Details of the parts related to the first conductive structure and the third conductive structure can be referred to the earlier description and will not be repeated here. The structure shown in FIG. 32, after subsequent processes such as the fabrication of redistribution layers, results in the package structure shown in FIG. 4. Referring to FIG. 32, when fabricating the second conductive structure in step S906, the depth of the through hole for the second conductive structure in the encapsulation material layer 4 is much smaller than that in the method shown in FIG. 7. This makes it easier to fill the conductive material, thereby enabling the fabrication of the second conductive structure with a higher density.

It is understood that the steps of the fabrication method and the features of the package structure described in the embodiments of the present invention may also be freely combined in other ways according to the needs to obtain different types of package structures. The embodiments of the present invention are not to be regarded as a limitation on the manner of combining the steps of the fabrication method and the features of the package structure.

Finally, it should be noted that the embodiments are only used to illustrate the technical solutions of the present application and are not intended to limit the same. Although the application has been described in detail with reference to the foregoing embodiments, a person of ordinary skill in the art should understand that the technical solutions of the foregoing embodiments may be modified or some of the technical features may be replaced by equivalent ones without causing the essence of the corresponding technical solutions to depart from the spirit and scope of the technical solutions of the embodiments of the present application.

1. A double-sided stacked fan-out package structure comprising:
a substrate with vias, having a first surface and a second surface, both of which are provided with stacked chips;
an encapsulation material layer filling at least some of the vias and encapsulating the chips and the substrate;
redistribution layers disposed on the encapsulation material layer and electrically connected to the chips;
a first conductive structure disposed in the encapsulation material layer on the first surface, the chips on the first surface being electrically connected to the redistribution layer on the first surface via the first conductive structure;
a second conductive structure extending through the thickness of the substrate and having at least some of sections disposed in at least some of the vias of the substrate, wherein the redistribution layers on the first surface and the second surface of the substrate are electrically connected through the second conductive structure;
package external pin pads disposed on the redistribution layer on the first surface of the substrate and electrically connected to the redistribution layer; and
BGA solder balls or solder chip pin bumps disposed on and electrically connected to the package external pin pads.

2. The package structure according to claim 1, wherein the vias disposed in the substrate include vias having an electrical connection function and vias not having an electrical connection function.

3. The package structure according to claim 1, wherein the vias in the substrate are simultaneously used as flow channels for an encapsulation material and as fabrication channels for the second conductive structure, all the vias are filled with the encapsulation material of the encapsulation material layer, and the second conductive structure is disposed within the encapsulation material of each via.

4. The package structure according to claim 1, wherein the vias in the substrate include a first via serving as a fabrication channel for the second conductive structure and a second via serving as a flow channel for an encapsulation material, the second conductive structure includes a conductive pillar section located in the first via and an interconnection line section located in the encapsulation material layer and electrically connected to a respective conductive pillar section, the first via is filled with the conductive pillar section of the second conductive structure, and the second via is filled with the encapsulation material of the encapsulation material layer.

5. The package structure according to claim 4, wherein the interconnection line section in the encapsulation material layer, which is electrically connected to the respective conductive pillar section, is electrically connected to the respective conductive pillar section in a coaxial manner.

6. The package structure according to claim 4, wherein the first via has a diameter smaller than the diameter of the second via, the number of first vias is larger than the number of second vias, and the density of the first vias is larger than the density of the second vias.

7. The package structure according to claim 1, wherein the chips are mounted via attachment materials on chip mounting regions of the first surface and the second surface of the substrate, and both the attachment materials and the substrate are made of thermally conductive materials; and
the attachment materials are selected from thermally conductive materials comprising metal alloy solder, silver paste, or nano-silver paste, and the substrate is made of thermally conductive materials comprising metal-based alloys, ceramics, graphene, or composite materials.

8. The package structure according to claim 7, wherein the chip mounting regions on the first and second surfaces of the substrate are further provided with heat dissipation holes for heat dissipation among chips.

9. The package structure according to claim 7, wherein the substrate is further provided with a step structure that is higher or lower than the chip mounting regions.

10. The package structure according to claim 1, wherein the package structure further comprises:
an insulating material layer on the second surface, which is disposed between the encapsulation material layer and the redistribution layer on the second surface; and
a third conductive structure in the insulating material layer on the second surface, wherein chips on the second surface are electrically connected to the redistribution layer on the second surface via the third conductive structure;
some sections of the second conductive structure extend through the insulating material layer.

11. The package structure according to claim 1, wherein the chips include pin pads, and pin bumps are provided on at least some of the pin pads of at least some of the chips; and
free end surfaces of the pin bumps on chips mounted on a same surface of the substrate lie in a same plane.

12. The package structure according to claim 11, wherein a functional surface of an uppermost chip on the first surface and/or the second surface of the substrate is not provided with a pin bump, and the free end surfaces of the pin bumps of the chips mounted on the same surface of the substrate are all flush with the functional surface of the uppermost chip on that surface.

13. A fabrication method of a package structure according to claim 3, comprising:
mounting at least one layer of chips respectively on regions for mounting chips on a first surface and a second surface of a substrate by means of layer stacking, wherein the substrate has vias extending through the thickness of the substrate;
covering the chips mounted on one surface of the substrate with a protective layer;
encapsulating a side of the substrate away from the protective layer with an encapsulation material, wherein during the encapsulating, the encapsulation material is able to flow through the vias to a side of the substrate where the protective layer is located, such that the chips mounted on both surfaces of the substrate are simultaneously encapsulated in one encapsulation process, and after the one encapsulation process, the substrate, as well as the chips mounted on both surfaces of the substrate except for chip surfaces covered by the protective layer, are encapsulated by the encapsulation material, and the vias of the substrate are filled with the encapsulation material;
fabricating conductive structures in the encapsulation material, comprising a first conductive structure located in an encapsulation material layer on the first surface and electrically connected to the chips mounted on the first surface, and a second conductive structure extending through the thickness of the substrate and disposed in the encapsulation material in at least some of the vias;
removing the protective layer to expose the chip surfaces covered by the protective layer from a surface of the encapsulation material;
fabricating redistribution layers on surfaces of the encapsulation material layer, which are electrically connected to the mounted chips via the conductive structures, wherein the redistribution layers on the first and second surfaces of the substrate are electrically connected via the second conductive structure;
fabricating package external pin pads on the redistribution layer on the first surface of the substrate, which are electrically connected to the redistribution layer; and
fabricating BGA solder balls or solder chip pin bumps on the package external pin pads.

14. The fabrication method according to claim 13, wherein the protective layer is a high-temperature-resistant protective film, comprising a film of PI or Teflon coated with a high-temperature adhesive film.

15. The fabrication method according to claim 13, wherein the chips are mounted on the substrate by means of layer stacking using attachment materials, with functional surfaces of the chips facing away from the substrate, and pin bumps of other chips mounted earlier than said chips are exposed; and
the attachment materials comprise metal alloy solder, silver paste, nano-silver paste, or other thermally conductive adhesives.

16. A fabrication method of a package structure according to claim 4, comprising:
fabricating a first via and a second via in a substrate, and fabricating a conductive pillar in the first via;
mounting at least one layer of chips respectively on regions for mounting chips on a first surface and a second surface of the substrate by means of layer stacking;
covering the chips mounted on one surface of the substrate with a protective layer;
encapsulating a side of the substrate away from the protective layer with encapsulation material, wherein during the encapsulating, the encapsulation material is able to flow through the second via to a side of the substrate where the protective layer is located, such that the chips mounted on both surfaces of the substrate are simultaneously encapsulated in one encapsulation process, and after the one encapsulation process, the substrate, as well as the chips mounted on both surfaces of the substrate except for chip surfaces covered by the protective layer, are encapsulated by the encapsulation material, and the second via of the substrate is filled with the encapsulation material;
removing the protective layer to expose the chip surfaces covered by the protective layer from a surface of the encapsulation material;
fabricating conductive structures in the encapsulation material, comprising a first conductive structure located in an encapsulation material layer on the first surface and electrically connected to the chips mounted on the first surface, and a second conductive structure extending through the thickness of the substrate, wherein the second conductive structure includes a conductive pillar section located in the first via and an interconnection line section located in the encapsulation material layer and electrically connected to a respective conductive pillar section;
fabricating redistribution layers on surfaces of the encapsulation material layer, which are electrically connected to the mounted chips via the conductive structures, wherein the redistribution layers on the first and second surfaces of the substrate are electrically connected via the second conductive structure;
fabricating package external pin pads on the redistribution layer on the first surface of the substrate, which are electrically connected to the redistribution layer; and
fabricating BGA solder balls or solder chip pin bumps on the package external pin pads.

17. The fabrication method according to claim 16, wherein the protective layer is a high-temperature-resistant protective film, comprising a film of PI or Teflon coated with a high-temperature adhesive film.

18. The fabrication method according to claim 16, wherein the chips are mounted on the substrate by means of layer stacking using attachment materials, with functional surfaces of the chips facing away from the substrate, and pin bumps of other chips mounted earlier than said chips are exposed;
the attachment materials comprise metal alloy solder, silver paste, nano-silver paste, or other thermally conductive adhesives.

19. A fabrication method of a package structure according to claim 10, comprising:
mounting at least one layer of chips respectively on regions for mounting chips on a first surface and a second surface of a substrate by means of layer stacking, wherein the substrate has vias extending through the thickness of the substrate;
covering the chips mounted on one surface of the substrate with a protective layer;
encapsulating a side of the substrate away from the protective layer with an encapsulation material, wherein during the encapsulating, the encapsulation material is able to flow through the vias to a side of the substrate where the protective layer is located, such that the chips mounted on both surfaces of the substrate are simultaneously encapsulated in one encapsulation process, and after the one encapsulation process, the substrate, as well as the chips mounted on both surfaces of the substrate except for chip surfaces covered by the protective layer, are encapsulated by the encapsulation material, and the vias of the substrate are filled with the encapsulation material;
fabricating a first conductive structure in the encapsulation material, wherein the first conductive structure is located in an encapsulation material layer on the first surface and is electrically connected to the chips mounted on the first surface;
removing the protective layer to expose the chip surfaces covered by the protective layer from a surface of the encapsulation material;
fabricating an insulating material layer on the encapsulation material layer on a side of the substrate covered by the protective layer, which encapsulates exposed chips;
fabricating a second conductive structure, which extends through the thickness of the substrate, in the encapsulation material of at least some of the vias and a corresponding insulating material layer, and fabricating a third conductive structure in the insulating material layer, wherein the chips on the second surface are electrically connected to a redistribution layer on the second surface via the third conductive structure;
fabricating redistribution layers on surfaces of the encapsulation material layer and the insulating material layer, respectively, wherein the redistributions layers are electrically connected to the mounted chips via the conductive structures, and the redistribution layers on the first and second surfaces of the substrate are electrically connected via the second conductive structure;
fabricating package external pin pads on the redistribution layer on the first surface of the substrate, which are electrically connected to the redistribution layer; and
fabricating BGA solder balls or solder chip pin bumps on the package external pin pads.

20. A fabrication method of a package structure according to claim 10, comprising:
fabricating a first via and a second via in a substrate, and fabricating a conductive pillar in the first via;
mounting at least one layer of chips respectively on regions for mounting chips on a first surface and a second surface of the substrate by means of layer stacking;
covering the chips mounted on one surface of the substrate with a protective layer;
encapsulating a side of the substrate away from the protective layer with an encapsulation material, wherein during the encapsulating, the encapsulation material is able to flow through the second via to a side of the substrate where the protective layer is located, such that the chips mounted on both surfaces of the substrate are simultaneously encapsulated in one encapsulation process, and after the one encapsulation process, the substrate, as well as the chips mounted on both surfaces of the substrate except for chip surfaces covered by the protective layer, are encapsulated by the encapsulation material, and the second via of the substrate is filled with the encapsulation material;
removing the protective layer to expose the chip surfaces covered by the protective layer from a surface of the encapsulation material;
fabricating an insulating material layer on an encapsulation material layer on a side of the substrate covered by the protective layer, which encapsulates exposed chips;
fabricating conductive structures in the encapsulation material layer and the insulating material layer, comprising a first conductive structure located in the encapsulation material layer on the first surface and electrically connected to the chips mounted on the first surface, a second conductive structure extending through the thickness of the substrate, and a third conductive structure located in the insulating material layer to electrically connect the chips on the second surface to a redistribution layer on the second surface, wherein the second conductive structure includes a conductive pillar section located in the first via and an interconnection line section located in the encapsulation material layer and the insulating material layer and electrically connected to a respective conductive pillar section;
fabricating redistribution layers on surfaces of the encapsulation material layer and the insulating material layer, wherein the redistribution layers are electrically connected to the mounted chips via the conductive structures, and the redistribution layers on the first and second surfaces of the substrate are electrically connected via the second conductive structure;
fabricating package external pin pads on the redistribution layer on the first surface of the substrate, which are electrically connected to the redistribution layer; and
fabricating BGA solder balls or solder chip pin bumps on the package external pin pads.
